(19) United States
(12) Patent Application Publication
(10) Pub. No.: US 2023/0343793 A1
(43) Pub. Date: Oct. 26, 2023

(54) ELECTRONIC DEVICE AND METHOD FOR MANUFACTURING THE SAME

(71) Applicant: InnoLux Corporation, Miao-Li County (TW)

(72) Inventors: Chandra LIUS, Miao-Li County (TW); Chung-Wen YEN, Miao-Li County (TW); Ai-Ling KUO, Miao-Li County (TW)

(21) Appl. No.: 18/187,995

(22) Filed: Mar. 22, 2023

(30) Foreign Application Priority Data
Apr. 24, 2022 (CN) 202210456046.9

(51) Int. Cl. H01L 27/12

(52) U.S. Cl. CPC H01L 27/124; H01L 27/1225; H01L 27/127

(57) ABSTRACT

An electronic device is provided. The electronic device includes a substrate, a first gate line disposed on the substrate, a first insulating layer disposed on the first gate line, a second insulating layer disposed on the first insulating layer, an oxide semiconductor layer disposed between the first insulating layer and the second insulating layer, a second gate line disposed on the second insulating layer, a third insulating layer disposed on the second gate line, and a first conductive element disposed on the third insulating layer, wherein the first conductive element is electrically connected to the first gate line by passing through the first insulating layer, the second insulating layer and the third insulating layer and is electrically connected to the second gate line by passing through the third insulating layer. The method for manufacturing the electronic device is also provided.

### CROSS REFERENCE TO RELATED APPLICATIONS

This application claims priority of China Patent Application No. 202210456046.9, filed on Apr. 24, 2022, the entirety of which is incorporated by reference herein.

### BACKGROUND

### Technical Field

The present disclosure relates to an electronic device, and in particular it relates to an electronic device in which a conductive element is connected to the gate lines of a double-gate transistor.

### Description of the Related Art

Low-temperature polycrystalline oxide (LTPO) circuits include a low-temperature polycrystalline silicon (LTPS) transistor and an indium gallium zinc oxide (IGZO) transistor. Since the IGZO transistor in the LTPO circuit has the characteristics of low leakage current, if the IGZO transistor is used to replace the transistor that needs to be turned on for a long time in the circuit, the energy-saving effect of the LTPO circuit can be improved.

However, since the electron mobility of IGZO transistors is lower than that of LTPS transistors, how to increase the driving speed of IGZO transistors plays an important role in terms of the overall performance of LTPO circuits.

### SUMMARY

In accordance with one embodiment of the present disclosure, an electronic device is provided. The electronic device includes a substrate, a first gate line disposed on the substrate, a first insulating layer disposed on the first gate line, a second insulating layer disposed on the first insulating layer, an oxide semiconductor layer disposed between the first insulating layer and the second insulating layer, a second gate line disposed on the second insulating layer, a third insulating layer disposed on the second gate line, and a first conductive element disposed on the third insulating layer. The first conductive element is electrically connected to the first gate line by passing through the first insulating layer, the second insulating layer and the third insulating layer, and is electrically connected to the second gate line by passing through the third insulating layer.

In accordance with one embodiment of the present disclosure, a method for manufacturing an electronic device is provided. The manufacturing method includes the following steps. A substrate is provided. A first gate line is formed on the substrate. A first insulating layer is formed on the first gate line. An oxide semiconductor layer is formed on the first insulating layer. A second insulating layer is formed on the oxide semiconductor layer. A second gate line is formed on the second insulating layer. A third insulating layer is formed on the second gate line. The third insulating layer is penetrated to expose a portion of the second gate line. The first insulating layer, the second insulating layer and the third insulating layer are penetrated to expose a portion of the first gate line. A first conductive element is formed on the third insulating layer, the portion of the first gate line and the portion of the second gate line, so that the first conductive element is electrically connected to the first gate line and the second gate line.

A detailed description is given in the following embodiments with reference to the accompanying drawings.

### BRIEF DESCRIPTION OF THE DRAWINGS

The disclosure can be more fully understood from the following detailed description when read with the accompanying figures. It is worth noting that in accordance with standard practice in the industry, various features are not drawn to scale. In fact, the dimensions of the various features may be arbitrarily increased or reduced for clarity of discussion.

FIG. 1 shows a top view of an electronic device in accordance with one embodiment of the present disclosure;

FIG. 2 shows a rear view of an electronic device in accordance with one embodiment of the present disclosure;

FIG. 3 shows a cross-sectional view of an electronic device in accordance with one embodiment of the present disclosure;

FIG. 4 shows a cross-sectional view of an electronic device in accordance with one embodiment of the present disclosure;

FIG. 5 shows a top view of an electronic device in accordance with one embodiment of the present disclosure;

FIG. 6 shows a cross-sectional view of an electronic device in accordance with one embodiment of the present disclosure;

FIG. 7 shows a cross-sectional view of an electronic device in accordance with one embodiment of the present disclosure;

FIG. 8 shows a top view of an electronic device in accordance with one embodiment of the present disclosure;

FIG. 9 shows a cross-sectional view of an electronic device in accordance with one embodiment of the present disclosure;

FIG. 10 shows a circuit diagram of an electronic device in accordance with one embodiment of the present disclosure;

FIG. 11 shows a circuit diagram of an electronic device in accordance with one embodiment of the present disclosure; and

FIGS. 12-14 show cross-sectional views of a method for manufacturing an electronic device in accordance with one embodiment of the present disclosure.

### DETAILED DESCRIPTION

Various embodiments or examples are provided in the following description to implement different features of the present disclosure. The elements and arrangement described in the following specific examples are merely provided for introducing the present disclosure and serve as examples without limiting the scope of the present disclosure. For example, when a first component is referred to as “on a second component”, it may directly contact the second component, or there may be other components in between, and the first component and the second component do not come in direct contact with one another.

It should be understood that additional operations may be provided before, during, and/or after the described method. In accordance with some embodiments, some of the stages (or steps) described below may be replaced or omitted.

In this specification, spatial terms may be used, such as “below”, “lower”, “above”, “higher” and similar terms, for briefly describing the relationship between an element relative to another element in the figures. Besides the directions illustrated in the figures, the devices may be used or operated in different directions. When the device is turned to different directions (such as rotated 45 degrees or other directions), the spatially related adjectives used in it will also be interpreted according to the turned position. In some embodiments of the present disclosure, terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

Herein, the terms “about”, “around” and “substantially” typically mean a value is in a range of +/−15% of a stated value, typically a range of +/−10% of the stated value, typically a range of +/−5% of the stated value, typically a range of +/−3% of the stated value, typically a range of +/−2% of the stated value, typically a range of +/−1% of the stated value, or typically a range of +/−0.5% of the stated value.

It should be understood that, although the terms “first”, “second”, “third”, etc. may be used herein to describe various elements, components, regions, layers, portions and/or sections, these elements, components, regions, layers, portions and/or sections should not be limited by these terms. These terms are only used to distinguish one element, component, region, layer, portion or section from another element, component, region, layer, portion or section. Thus, a first element, component, region, layer, portion or section discussed below could be termed a second element, component, region, layer, portion or section without departing from the teachings of the present disclosure.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

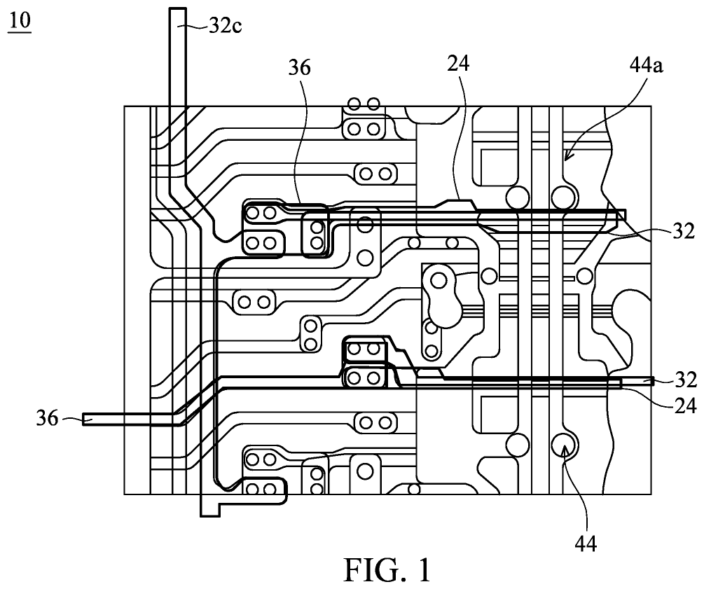

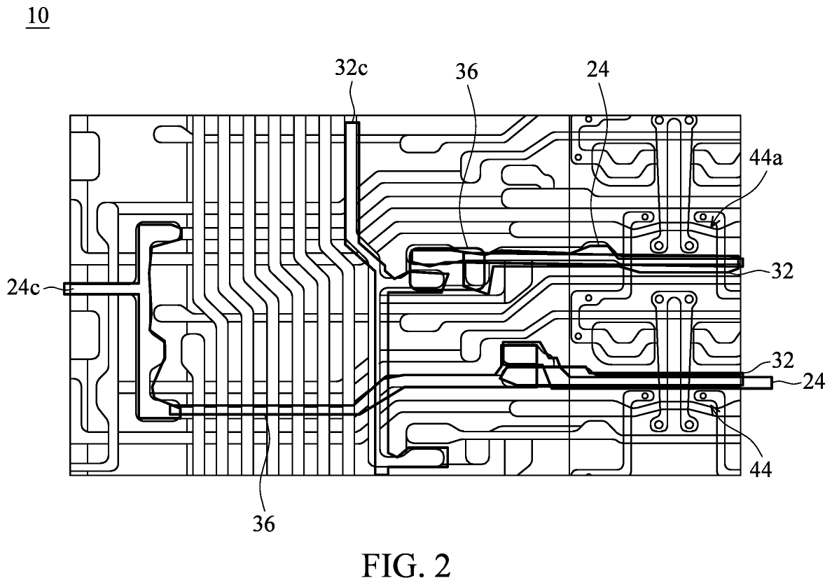

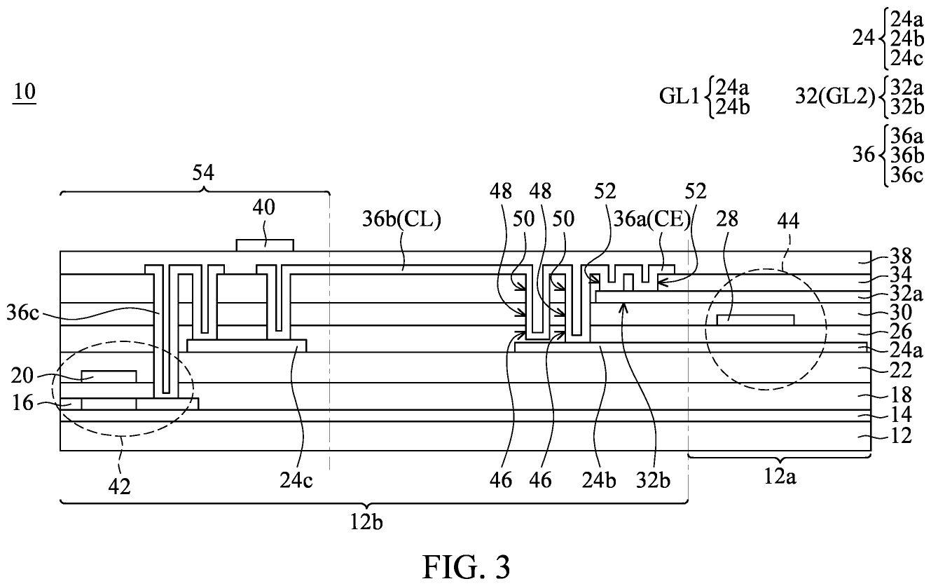

Referring to FIGS. 1-3, in accordance with one embodiment of the present disclosure, an electronic device 10 is provided. FIG. 1 is the top view of the electronic device 10. FIG. 2 is the rear view of the electronic device 10. FIG. 3 is the cross-sectional view of the electronic device 10.

As shown in FIG. 3, the electronic device 10 includes a substrate 12, a first insulating layer 14, a first semiconductor layer 16, a second insulating layer 18, a gate electrode 20, a third insulating layer 22, a first metal layer 24, a fourth insulating layer 26, an oxide semiconductor layer 28, a fifth insulating layer 30, a second metal layer 32, a sixth insulating layer 34, a third metal layer 36, a seventh insulating layer 38, and a fourth metal layer 40. The substrate 12 includes an active region 12a and a peripheral region 12b adjacent to the active region 12a. The first insulating layer 14 is disposed on the substrate 12. The first semiconductor layer 16 is disposed on the first insulating layer 14 and located in the peripheral region 12b of the substrate 12. The second insulating layer 18 is disposed on the first insulating layer 14 and covers the first semiconductor layer 16. In FIG. 3, the transistor 42 is located in the peripheral region 12b of the substrate 12. The transistor 42 may include the first semiconductor layer 16 (an active layer) and the gate electrode 20. The gate electrode 20 is disposed on the second insulating layer 18, corresponding to the position of the first semiconductor layer 16. The third insulating layer 22 is disposed on the second insulating layer 18 and covers the gate electrode 20. The first metal layer 24 is disposed on the third insulating layer 22. The first metal layer 24 includes a first portion 24a, a second portion 24b and a third portion 24c. The first portion 24a is located in the active region 12a of the substrate 12. The second portion 24b is located in the peripheral region 12b of the substrate 12 and connected to the first portion 24a. The third portion 24c is located in the peripheral region 12b of the substrate 12 and separated from the second portion 24b. The fourth insulating layer 26 is disposed on the third insulating layer 22 and covers the first metal layer 24. The fourth insulating layer 26 has an opening 46. In FIG. 3, the number of the opening 46 is two. In some embodiments, the number of the opening 46 may include other numbers, such as one or more than two. The oxide semiconductor layer 28 is located in the active region 12a of the substrate 12 and disposed on the fourth insulating layer 26. The fifth insulating layer 30 is disposed on the fourth insulating layer 26 and covers the oxide semiconductor layer 28. The fifth insulating layer 30 has an opening 48. In FIG. 3, the number of the opening 48 is two. In some embodiments, the number of the opening 48 may include other numbers, such as one or more than two. The second metal layer 32 is disposed on the fifth insulating layer 30. The second metal layer 32 includes a first portion 32a and a second portion 32b. The first portion 32a is located in the active region 12a of the substrate 12. The second portion 32b is located in the peripheral region 12b of the substrate 12 and connected to the first portion 32a. In FIG. 3, the transistor 44 is disposed on the active region 12a of the substrate 12. In some embodiments, the transistor 44 may be a double-gate transistor. The transistor 44 may include the oxide semiconductor layer 28. The oxide semiconductor layer 28 may include indium gallium zinc oxide (IGZO). A first gate line GL1 may include the first portion 24a and the second portion 24b of the first metal layer 24. A second gate line GL2 may include the first portion 32a and the second portion 32b of the second metal layer 32. The first gate line GL1 and the second gate line GL2 can be used to provide a gate signal to the transistor 44. In addition, the first gate line GL1 may be used as a bottom gate of the transistor 44. The second gate line GL2 may be used as a top gate of the transistor 44, but not limited thereto. The sixth insulating layer 34 is disposed on the fifth insulating layer 30 and covers the second metal layer 32. The sixth insulating layer 34 has an opening 50. In FIG. 3, the number of the opening 50 is two. In some embodiments, the number of the opening 50 may include other numbers, such as one or more than two. In FIG. 3, the opening 50 overlaps the opening 46 and the opening 48. The sixth insulating layer 34 further includes an opening 52 adjacent to the opening 50. In FIG. 3, the number of the opening 52 is two. In some embodiments, the number of the opening 52 may include other numbers, such as one or more than two. The third metal layer 36 is disposed on the sixth insulating layer 34. The third metal layer 36 includes a first portion 36a, a second portion 36b and a third portion 36c. In some embodiments, the conductive element CE may be the first portion 36a of the third metal layer 36. The conductive element CE may be electrically connected to the second portion 24b of the first metal layer 24 through the fourth insulating layer 26, the fifth insulating layer 30 and the sixth insulating layer 34. The conductive element CE may be electrically connected to the second portion 32b of the second metal layer 32 through the sixth insulating layer 34. In more detail, in FIG. 3, the conductive element CE is electrically connected to the first gate line GL1 through the opening 46, the opening 48 and the opening 50. The conductive element CE is electrically connected to the second gate line GL2 through the opening 52. The connection line CL is electrically connected to the first portion 36a of the third metal layer 36, and electrically connected to the third portion 24c of the first metal layer 24. In the embodiment, the connection line CL may be the second portion 36b of the third metal layer 36, but is not limited thereto. The third portion 36c of the third metal layer 36 serves as a drain/source of the transistor 42 electrically connecting the first semiconductor layer 16 and the third portion 24c of the first metal layer 24. The seventh insulating layer 38 is disposed on the sixth insulating layer 34 and covers the third metal layer 36. The fourth metal layer 40 is disposed on the seventh insulating layer 38, located in the peripheral region 12b of the substrate 12, corresponding to the position of the third portion 24c of the first metal layer 24. A driving circuit 54 is disposed on the peripheral region 12b of the substrate 12. The driving circuit 54 may be, for example, the gate on panel (GOP). In FIG. 3, the driving circuit 54 may include the transistor 42. The connection line CL may be electrically connected to the driving circuit 54 and the conductive element CE.

It should be noted that the third metal layer 36 here refers to the layer-to-layer positional relationship or formation sequence, and is not limited to the formation of the same process or the same material. That is, the third metal layer 36 is located on the first metal layer 24 and the second metal layer 32, or the third metal layer 36 is formed behind the first metal layer 24 and the second metal layer 32. The different portions of the third metal layer 36 may be formed by different processes or different materials. For example, the material of the first portion 36a of the third metal layer 36 may be different from the material of the second portion 36b of the third metal layer 36, or the first portion 36a of the third metal layer 36 and the second portion 36b of the third metal layer 36 are formed by different processes.

In some embodiments, the substrate 12 may include a rigid substrate, such as a glass substrate, but the present disclosure is not limited thereto, and other suitable rigid substrate materials are also applicable to the present disclosure. The substrate 12 may include a flexible substrate, such as a polyimide (PI) substrate, but the present disclosure is not limited thereto, and other suitable flexible substrate materials are also applicable to the present disclosure.

In some embodiments, the first insulating layer 14, the second insulating layer 18, the third insulating layer 22, the fourth insulating layer 26, the fifth insulating layer 30, the sixth insulating layer 34, and the seventh insulating layer 38 may include organic insulating materials or inorganic insulating materials, for example, silicon oxide, silicon nitride, silicon oxynitride or a combination thereof, but the present disclosure is not limited thereto, and other suitable organic or inorganic insulating materials are also applicable to the present disclosure.

In some embodiments, the first semiconductor layer 16 may include low-temperature polycrystalline silicon (LTPS), but the present disclosure is not limited thereto, and other suitable semiconductor materials are also applicable to the present disclosure. In some embodiments, when the material selected for the first semiconductor layer 16 is LTPS, the transistor 42 is a LTPS transistor. In some embodiments, the gate electrode 20, the first metal layer 24, the second metal layer 32, and the fourth metal layer 40 may include molybdenum, aluminum, copper or titanium, but the present disclosure is not limited thereto, and other suitable conductive materials are also applicable to the present disclosure. In some embodiments, the oxide semiconductor layer 28 may include indium gallium zinc oxide (IGZO), but the present disclosure is not limited thereto, and other suitable semiconductor or oxide semiconductor materials are also applicable to the present disclosure. In some embodiments, when the material selected for the oxide semiconductor layer 28 is IGZO, the transistor 44 is an IGZO double-gate transistor. In some embodiments, the third metal layer 36 may include molybdenum, aluminum, copper, titanium or a combination thereof, such as molybdenum/aluminum/molybdenum, titanium/aluminum/titanium or titanium/aluminum/molybdenum, but the present disclosure is not limited thereto, and other suitable conductive materials are also applicable to the present disclosure.

In some embodiments, the conductivity of the material of the connection line CL may be greater than the conductivity of the material of the first gate line GL1 and/or the conductivity of the material of the second gate line GL2. For example, in terms of material selection, molybdenum (Mo) may be used for the first metal layer 24 and the second metal layer 32, and aluminum (Al) with better conductivity may be used for the third metal layer 36, so the material of the connection line CL may be adjusted to improve signal conduction effect.

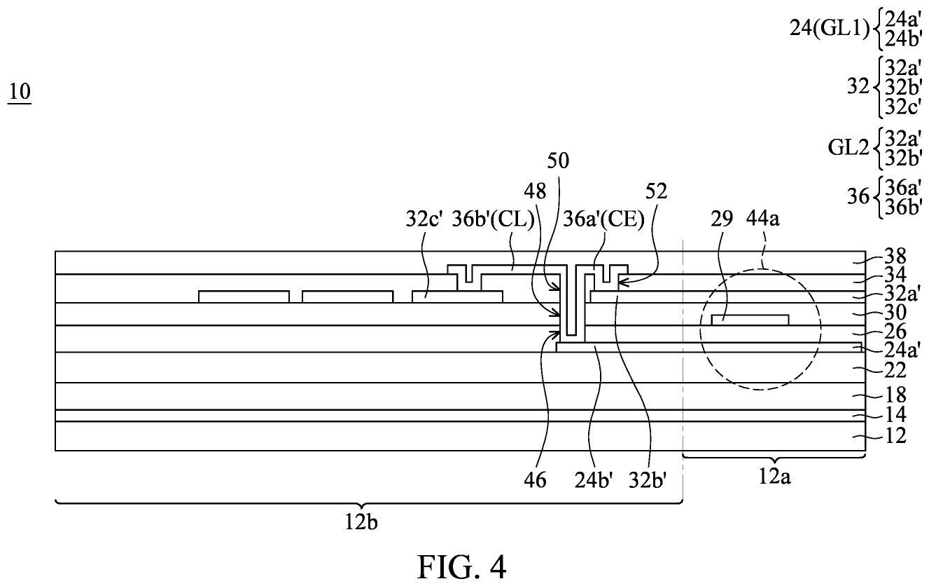

Referring to FIGS. 1, 2 and 4, the configuration of another transistor 44a in the electronic device 10 and the electrical connection relationship with each element are illustrated. In FIG. 4, the portions similar to those disclosed in FIG. 3 will not be described again. The first metal layer 24 includes a first portion 24a′ and a second portion 24b′. The first portion 24a′ is located in the active region 12a of the substrate 12. The second portion 24b′ is located in the peripheral region 12b of the substrate 12 and is connected to the first portion 24a′. An oxide semiconductor layer 29 is located in the active region 12a of the substrate 12. The second metal layer 32 includes a first portion 32a′, a second portion 32b′ and a third portion 32c′. The first portion 32a′ is located in the active region 12a of the substrate 12. The second portion 32b′ is located in the peripheral region 12b of the substrate 12 and is connected to the first portion 32a′. The third portion 32c′ is located in the peripheral region 12b of the substrate 12 and is separated from the second portion 32b′. In FIG. 4, the transistor 44a may be disposed on the active region 12a of the substrate 12. In some embodiments, the transistor 44a may be a double-gate transistor. The transistor 44a may include the oxide semiconductor layer 29. The oxide semiconductor layer 29 may include indium gallium zinc oxide (IGZO). The first gate line GL1 may include the first portion 24a′ and the second portion 24b′ of the first metal layer 24. The second gate line GL2 may include the first portion 32a′ and the second portion 32b′ of the second metal layer 32. The number of the opening 46 may include other numbers, such as two or more. The fifth insulating layer 30 has the opening 48, the number of which is one. In some embodiments, the number of the opening 48 may include other numbers, such as two or more. The sixth insulating layer 34 has the opening 50, the number of which is one. In some embodiments, the number of the opening 50 may include other numbers, such as two or more. In FIG. 4, the opening 50 overlaps the opening 46 and the opening 48. The sixth insulating layer 34 further includes the opening 52 adjacent to the opening 50, the number of which is one. In some embodiments, the number of the opening 52 may include other numbers, such as two or more. The third metal layer 36 is located in the peripheral region 12b of the substrate 12. The third metal layer 36 includes a first portion 36a′ and a second portion 36b′. In some embodiments, the conductive element CE may be the first portion 36a′ of the third metal layer 36. The conductive element CE may pass through the fourth insulating layer 26, the fifth insulating layer 30 and the sixth insulating layer 34 to electrically connect to the second portion 24b′ of the first metal layer 24, and pass through the sixth insulating layer 34 to electrically connect to the second portion 32b′ of the second metal layer 32. In more detail, in FIG. 4, the conductive element CE is electrically connected to the first gate line GL1 through the opening 46, the opening 48 and the opening 50. The conductive element CE is electrically connected to the second gate line GL2 through the opening 52. The connection line CL is connected to the third portion 32c′ of the second metal layer 32. The connection line CL is electrically connected to the conductive element CE.

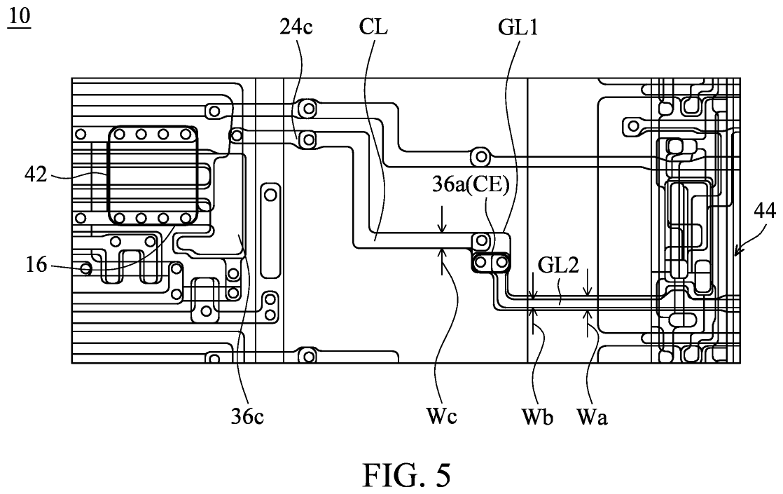

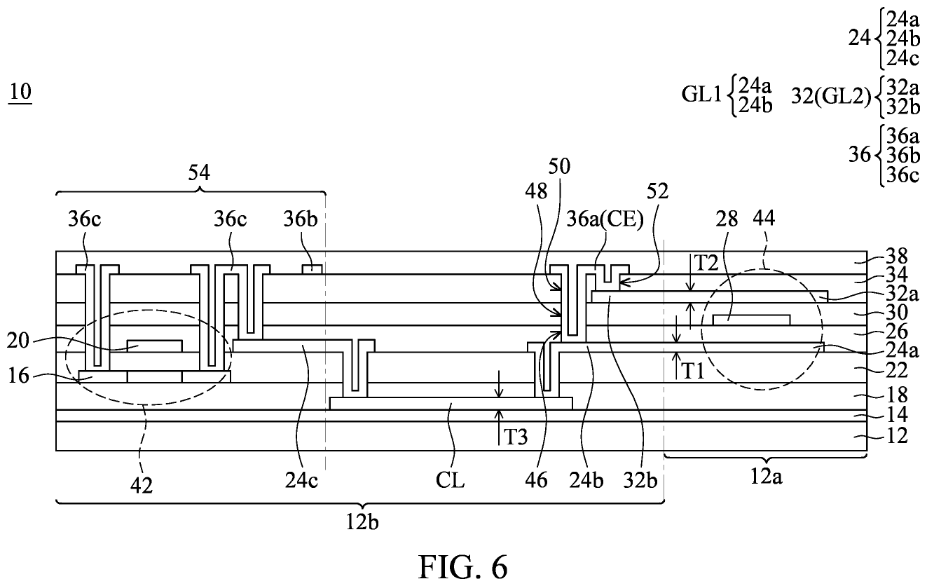

Referring to FIGS. 5 and 6, in accordance with one embodiment of the present disclosure, an electronic device 10 is provided. FIG. 5 is the top view of the electronic device 10. FIG. 6 is the cross-sectional view of the electronic device 10.

In FIG. 6, the portions similar to those disclosed in FIG. 3 will not be described again. The fourth insulating layer 26 has the opening 46, the number of which is one. In some embodiments, the number of the opening 46 may include other numbers, such as two or more. The fifth insulating layer 30 has the opening 48, the number of which is one. In some embodiments, the number of the opening 48 may include other numbers, such as two or more. The sixth insulating layer 34 has the opening 50, the number of which is one. In some embodiments, the number of the opening 50 may include other numbers, such as two or more. In FIG. 6, the opening 50 overlaps the opening 46 and the opening 48. The sixth insulating layer 34 further includes the opening 52 adjacent to the opening 50, the number of which is one. In some embodiments, the number of the opening 52 may include other numbers, such as two or more. The third metal layer 36 is located in the peripheral region 12b of the substrate 12. The third metal layer 36 includes a first portion 36a, a second portion 36b and a third portion 36c. In some embodiments, the conductive element CE may be the first portion 36a of the third metal layer 36. The conductive element CE may pass through the fourth insulating layer 26, the fifth insulating layer 30 and the sixth insulating layer 34 to electrically connect to the second portion 24b of the first metal layer 24, and pass through the sixth insulating layer 34 to electrically connect to the second portion 32b of the second metal layer 32. In more detail, in FIG. 6, the conductive element CE is electrically connected to the first gate line GL1 through the opening 46, the opening 48 and the opening 50. The conductive element CE is electrically connected to the second gate line GL2 through the opening 52. The second portion 36b is separated from the first portion 36a of the third metal layer 36. The third portion 36c of the third metal layer 36 serves as the source/drain of the transistor 42, electrically connecting the first semiconductor layer 16 and the third portion 24c of the first metal layer 24. It should be noted that the connection line CL is electrically connected to the third portion 24c of the first metal layer 24 and the second portion 24b of the first metal layer 24. In some embodiments, the thickness T3 of the connection line CL is greater than the thickness T1 of the first gate line GL1 or the thickness T2 of the second gate line GL2. In some embodiments, as shown in FIG. 5, the width We of the connection line CL is greater than the width Wa of the first gate line GL1 or the width Wb of the second gate line GL2. In the present disclosure, the signal conduction effect can be improved by adjusting the thickness or width of the connection line CL. In FIG. 6, the driving circuit 54 is disposed on the peripheral region 12b of the substrate 12. The driving circuit 54 may be, for example, the gate on panel (GOP). The driving circuit 54 may include the transistor 42. The connection line CL may be electrically connected to the driving circuit 54 and the conductive element CE.

According to the top view (FIG. 5) of the electronic device 10, the electrical connection relationship between the transistor 44 and each element in the electronic device is described. The conductive element CE (i.e. the first portion 36a of the third metal layer 36) is electrically connected to the first gate line GL1 and the second gate line GL2. The connection line CL is electrically connected to the third portion 24c of the first metal layer 24 and the second portion 24b of the first metal layer 24. The third portion 36c of the third metal layer 36 is electrically connected to the first semiconductor layer 16 of the transistor 42 and the third portion 24c of the first metal layer 24.

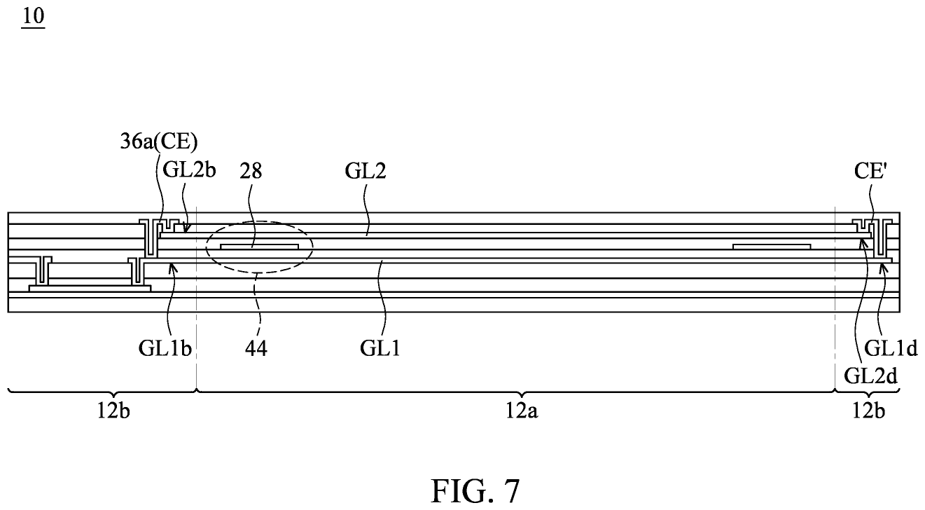

Referring to FIG. 7, in accordance with one embodiment of the present disclosure, an electronic device 10 is provided. FIG. 7 is the cross-sectional view of the electronic device 10.

In FIG. 7, the portions similar to those disclosed in FIG. 6 will not be described again. The main difference from FIG. 6 is that the electronic device 10 disclosed in FIG. 7 further includes a second conductive element disposed on the other end of the transistor 44, electrically connected to the gate line of the transistor 44. The details are as follows. The first gate line GL1 has two ends (GL1b and GL1d). The second gate line GL2 has two ends (GL2b and GL2d). The first conductive element CE is disposed on the peripheral region 12b of the substrate 12. In some embodiments, the first conductive element CE may be the first portion 36a of the third metal layer 36, electrically connected to one (for example, the end GL1b) of the two ends (GL1b and GL1d) of the first gate line GL1, and electrically connected to one (for example, the end GL2b) of the two ends (GL2b and GL2d) of the second gate line GL2. The second conductive element CE′ may be disposed on the peripheral region 12b of the substrate 12. In some embodiments, the second conductive element CE′ may be electrically connected to the other (for example, the end GL1d) of the two ends (GL1b and GL1d) of the first gate line GL1, and electrically connected to the other (for example, the end GL2d) of the two ends (GL2b and GL2d) of the second gate line GL2. One of the two ends (GL1b and GL1d) of the first gate line GL1 is adjacent to one of the two ends (GL2b and GL2d) of the second gate line GL2. For example, the end GL1b of the first gate line GL1 is adjacent to the end GL2b of the second gate line GL2. The end GL1d of the first gate line GL1 is adjacent to the end GL2d of the second gate line GL2.

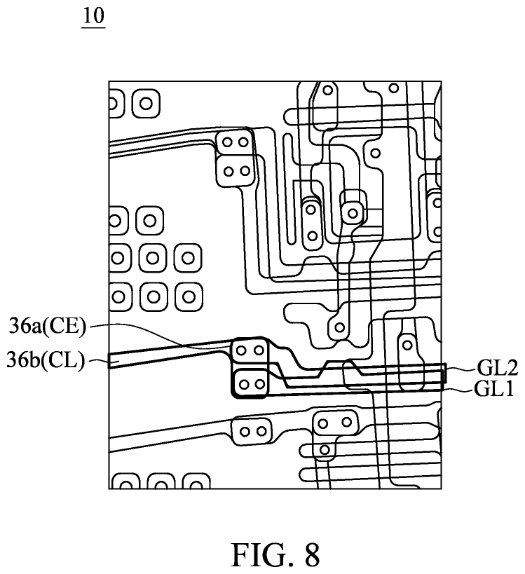

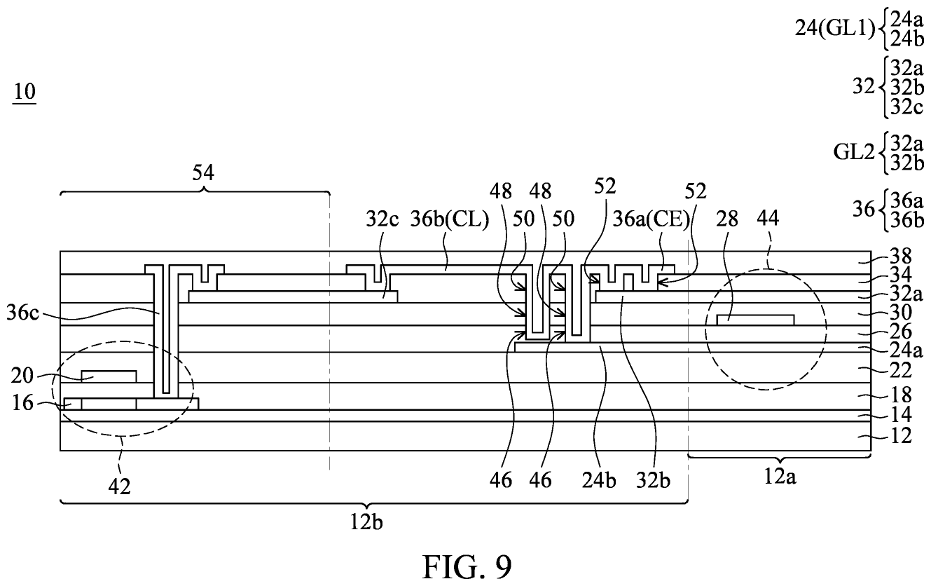

Referring to FIGS. 8 and 9, in accordance with one embodiment of the present disclosure, an electronic device 10 is provided. FIG. 8 is the top view of the electronic device 10. FIG. 9 is the cross-sectional view of the electronic device 10.

In FIG. 9, the portions similar to those disclosed in FIG. 3 will not be described again. The first metal layer 24 includes a first portion 24a and a second portion 24b. The first portion 24a is located in the active area 12a of the substrate 12. The second portion 24b is connected to the first portion 24a and located in the peripheral area 12b of the substrate 12. The second metal layer 32 includes a first portion 32a, a second portion 32b and a third portion 32c. The first portion 32a is located in the active region 12a of the substrate 12. The second portion 32b is connected to the first portion 32a and located in the peripheral region 12b of the substrate 12. The third portion 32c is separated from the second portion 32b and located in the peripheral region 12b of the substrate 12. The third metal layer 36 includes a first portion 36a and a second portion 36b located in the peripheral area 12b of the substrate 12. It should be noted that the connection line CL may be the second portion 36b of the third metal layer 36 and connected to the conductive element CE, and electrically connected to the third portion 32c of the second metal layer 32. The third portion 36c of the third metal layer 36 serves as the source/drain of the transistor 42, and is electrically connected to the first semiconductor layer 16 and the third portion 32c of the second metal layer 32.

According to the top view (FIG. 8) of the electronic device 10, the electrical connection relationship with each element in the electronic device 10 is described. The conductive element CE is electrically connected to the first gate line GL1 and the second gate line GL2. The connection line CL is connected to an external circuit (not shown).

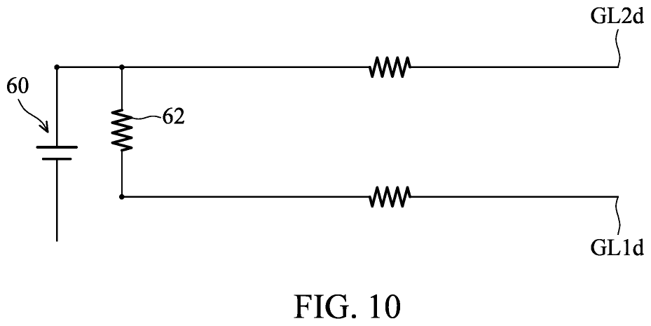

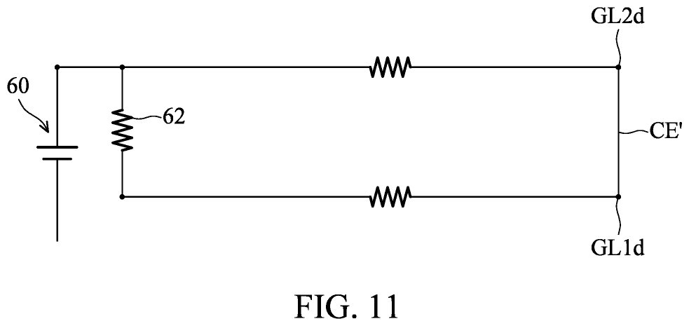

Referring to FIGS. 10 and 11, the electronic device 10 shown in FIG. 7 is taken as an example to illustrate that, when the switching impedance in the device is too large, whether to add a second conductive element in the other end of the transistor 44 and make the second conductive element electrically connected to the gate line of the transistor 44 will affect signal transmission.

The reasons for the excessive switching impedance in the device include that the opening made by etching is too small, resulting in insufficient contact area of the metal layer for electrical connection, or the etching gas damages the surface of the metal layer during the process of etching the opening, etc. FIG. 10 is the circuit diagram of the electronic device. In the circuit design, no conductive element is provided in the other end of the double-gate transistor, that is, one end of the gate lines of the double-gate transistor is not electrically connected to each other. FIG. 11 is the circuit diagram of the electronic device. In the circuit design, a conductive element is added to the other end of the double-gate transistor, that is, both ends of the gate lines of the double-gate transistor are electrically connected to each other. In FIG. 10, when the signal 60 provided by the external circuit produces a switching impedance 62 during the transmission process, since one end of the gate lines of the double-gate transistor is not electrically connected to each other (for example, the end GL1d of the first gate line GL1 is not electrically connected to the end GL2d of the second gate line GL2), the signal of one of the gate lines is abnormal. In contrast, in FIG. 11, when the signal 60 provided by the external circuit produces a switching impedance 62 during the transmission process, since both ends of the gate lines of the double-gate transistor are electrically connected to each other (for example, the end GL1d of the first gate line GL1 is electrically connected to the end GL2d of the second gate line GL2 through the conductive element CE′), the two gate lines of the double-gate transistor obtain the same potential to achieve the effect of stable signal transmission.

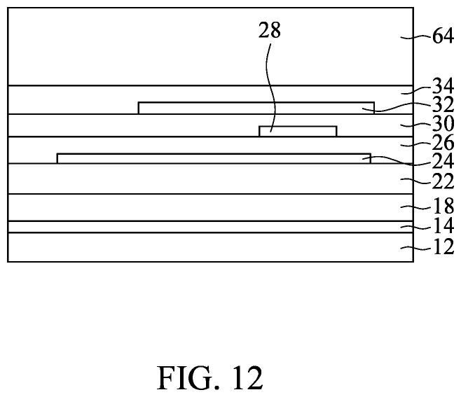

Referring to FIGS. 12 to 14, in accordance with one embodiment of the present disclosure, a method for manufacturing an electronic device is provided. FIGS. 12 to 14 are the cross-sectional views of the manufacturing method of the electronic device. Some elements in the electronic device are omitted in the figures for convenience of description.

First, as shown in FIG. 12, a substrate 12 is provided, on which a first insulating layer 14, a second insulating layer 18, a third insulating layer 22, a first metal layer 24, a fourth insulating layer 26, an oxide semiconductor layer 28, a fifth insulating layer 30, a second metal layer 32, a sixth insulating layer 34 and a photoresist layer 64 are sequentially formed.

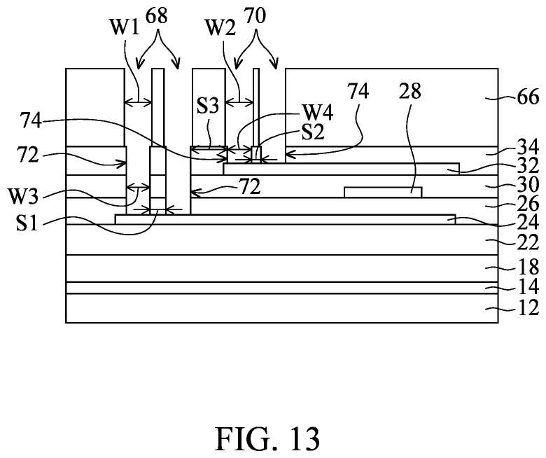

Next, as shown in FIG. 13, the photoresist layer 64 is patterned to form a patterned photoresist layer 66. The patterned photoresist layer 66 includes a first opening 68 and a second opening 70. In FIG. 13, the number of the first opening 68 is two. The number of the second opening 70 is two. In some embodiments, the number of the first opening 68 and the second opening 70 may include other numbers, such as one or more than two. Next, using the patterned photoresist layer 66 as an etching mask, the insulating layers under the patterned photoresist layer 66 are etched to form a third opening 72 and a fourth opening 74, respectively exposing a portion of the first metal layer 24 and a portion of the second metal layer 32. The number of the third opening 72 is two, which pass through the fourth insulating layer 26, the fifth insulating layer 30 and the sixth insulating layer 34, exposing a portion of the first metal layer 24. The number of the fourth opening 74 is two, which pass through the sixth insulating layer 34 and expose a portion of the second metal layer 32.

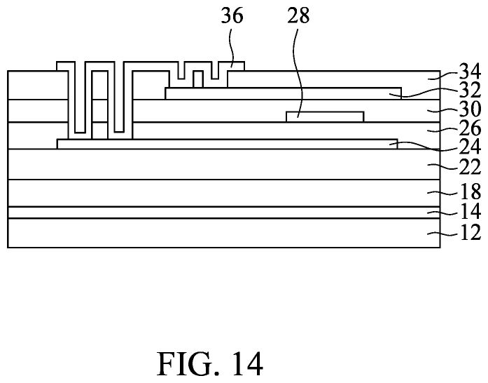

Next, as shown in FIG. 14, a third metal layer 36 is formed on the sixth insulating layer 34, and fills the third opening 72 and the fourth opening 74 to form on the exposed first metal layer 24 and the second metal layer 32, so that the third metal layer 36 is electrically connected to the first metal layer 24 and the second metal layer 32. So far, the fabrication of the conductive elements in the electronic device is completed. It should be noted that, in some embodiments, the step of etching through the sixth insulating layer 34 and the step of etching through the fourth insulating layer 26, the fifth insulating layer 30 and the sixth insulating layer 34 are implemented in the same process.

Referring to FIG. 13, the size relationship of each opening in the structure of the electronic device is further described.

As shown in FIG. 13, the width of the first opening 68 is W1. The width of the second opening 70 is W2. The width of the third opening 72 is W3. The width of the fourth opening 74 is W4. The spacing between the third openings 72 is S1. The spacing between the fourth openings 74 is S2. The spacing between the third opening 72 and the fourth opening 74 is S3. In FIG. 13, the width W1 of the first opening 68 is greater than the width W2 of the second opening 70. The width W3 of the third opening 72 is greater than the width W4 of the fourth opening 74. The width W1 of the first opening 68 is greater than the width W3 of the third opening 72. The width W2 of the second opening 70 is greater than the width W4 of the fourth opening 74. The spacing S1 between the third openings 72 is smaller than the spacing S3 between the third openings 72 and the fourth openings 74. The spacing S2 between the fourth openings 74 is smaller than the spacing S3 between the third openings 72 and the fourth openings 74. In some embodiments, the width W3 of the third opening 72 and the width W4 of the fourth opening 74 are approximately between 2 μm and 4 μm. In some embodiments, the spacing S1 of the first openings 68 and the spacing S2 of the second openings 70 are approximately between 0.5 μm and 2 μm. In some embodiments, the spacing S3 between the first opening 68 and the second opening 70 is approximately between 3 μm and 5 μm. It should be noted that the width W3 (i.e. the width of the bottom of the opening) of the third opening 72 and the width W4 (i.e. the width of the bottom of the opening) of the fourth opening 74 should not be too small to reduce poor electrical contact. However, an excessively large size also occupies more space. The spacing S1 between the first openings 68 and the spacing S2 between the second openings 70 should not be too small to reduce the possibility of collapse of the opening structure, but also should not be too large to reduce the occupied area. In addition, the spacing S3 between the first opening 68 and the second opening 70 can be appropriately large to reduce the connection between the third opening 72 and the fourth opening 74, resulting in excessive impedance and failure of the upper and lower gate lines at the same time.

In the present disclosure, a metal conductive element is used to simultaneously connect to the top gate and the bottom gate of the double-gate transistor. The circuit design enables channels to be formed on the upper and lower surfaces of the conductor layer, which can effectively increase the driving speed (I_{ON}) of the transistor. In the present disclosure, the electrical signal provided by the external circuit (for example, flexible printed circuit board (FPC) or chip-on-film (COF)) can be transmitted to the metal conductive element through the connection line on the upper layer, and then drive the top gate and bottom gate of the double-gate transistor, or it is firstly transmitted to the bottom gate of the double-gate transistor through the connection line on the lower layer, and then transmitted to the top gate of the double-gate transistor through the metal conductive element. If the top gate and the bottom gate are directly connected to each other, more photolithography process steps are required, and the line impedance of the bottom gate is also increased, causing the RC load of the bottom gate to be greater than that of the top gate, resulting in a potential difference between the top and bottom gates. The disclosed method of fabricating the metal conductive element connecting the top gate and the bottom gate at the same time (that is, forming openings with different depths simultaneously in the same process) has fewer photolithography process steps. In the present disclosure, increasing the number of switching openings can reduce the risk of overall signal switching failure due to excessive switching impedance of a single opening. In the present disclosure, the effect of signal transmission can be improved by adjusting the material (chosen to have better conductivity), thickness or width of the connection line. In addition, the metal conductive element of the present disclosure is electrically connected to the top gate and the bottom gate through the openings corresponding to the top gate and the bottom gate respectively, so as to increase the contact area of the top gate and the bottom gate for the electrical connection, which can reduce the switching impedance.

Although some embodiments of the present disclosure and their advantages have been described in detail, it should be understood that various changes, substitutions and alterations can be made herein without departing from the spirit and scope of the disclosure as defined by the appended claims. The features of the various embodiments can be used in any combination as long as they do not depart from the spirit and scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods or steps. In addition, each claim constitutes an individual embodiment, and the claimed scope of the present disclosure includes the combinations of the claims and embodiments. The scope of protection of present disclosure is subject to the definition of the scope of the appended claims. Any embodiment or claim of the present disclosure does not need to meet all the purposes, advantages, and features disclosed in the present disclosure.

What is claimed is:

1. An electronic device, comprising:
a substrate;
a first gate line disposed on the substrate;
a first insulating layer disposed on the first gate line;
a second insulating layer disposed on the first insulating layer;
an oxide semiconductor layer disposed between the first insulating layer and the second insulating layer;
a second gate line disposed on the second insulating layer;
a third insulating layer disposed on the second gate line; and
a first conductive element disposed on the third insulating layer, wherein the first conductive element is electrically connected to the first gate line by passing through the first insulating layer, the second insulating layer and the third insulating layer and is electrically connected to the second gate line by passing through the third insulating layer.

2. The electronic device as claimed in claim 1, further comprising a second conductive element, wherein the first gate line has two ends, the second gate line has two ends, the first conductive element is electrically connected to one of the two ends of the first gate line and one of the two ends of the second gate line, the second conductive element is electrically connected to the other one of the two ends of the first gate line and the other one of the two ends of the second gate line, and the one of the two ends of the first gate line is adjacent to the one of the two ends of the second gate line.

3. The electronic device as claimed in claim 1, wherein the first insulating layer has a first opening, the second insulating layer has a second opening, the third insulating layer has a third opening, in a cross-sectional view of the electronic device, the third opening overlaps the first opening and the second opening, and the first conductive element is electrically connected to the first gate line through the first opening, the second opening and the third opening.

4. The electronic device as claimed in claim 3, wherein there is more than one first opening, there is more than one second opening, and there is more than one third opening.

5. The electronic device as claimed in claim 1, wherein the third insulating layer has a fourth opening, and the first conductive element is electrically connected to the second gate line through the fourth opening.

6. The electronic device as claimed in claim 5, wherein there is more than one fourth opening.

7. The electronic device as claimed in claim 1, wherein the oxide semiconductor layer comprises indium gallium zinc oxide (IGZO).

8. The electronic device as claimed in claim 1, further comprising a driving circuit and a connection line electrically connected to the driving circuit and the first conductive element, wherein the substrate comprises an active region and a peripheral region adjacent to the active region, the driving circuit is disposed in the peripheral region, and the oxide semiconductor layer is disposed in the active region.

9. The electronic device as claimed in claim 8, wherein the connection line has a conductivity greater than that of the first gate line or the second gate line.

10. The electronic device as claimed in claim 8, wherein, in a top view of the electronic device, the connection line has a width larger than that of the first gate line or the second gate line.

11. The electronic device as claimed in claim 8, wherein, in a cross-sectional view of the electronic device, the connection line has a thickness larger than that of the first gate line or the second gate line.

12. The electronic device as claimed in claim 8, wherein the driving circuit comprises a gate on panel (GOP).

13. The electronic device as claimed in claim 8, wherein the driving circuit comprises a transistor having a semiconductor layer.

14. The electronic device as claimed in claim 13, wherein the semiconductor layer comprises low-temperature polycrystalline silicon (LTPS).

15. The electronic device as claimed in claim 8, wherein the connection line is disposed above the second gate line.

16. The electronic device as claimed in claim 8, wherein the connection line is disposed below the first gate line.

17. A method for manufacturing an electronic device, comprising:
providing a substrate;
forming a first gate line on the substrate;
forming a first insulating layer on the first gate line;
forming an oxide semiconductor layer on the first insulating layer;
forming a second insulating layer on the oxide semiconductor layer;
forming a second gate line on the second insulating layer;
forming a third insulating layer on the second gate line;
penetrating the third insulating layer to expose a portion of the second gate line;
penetrating the first insulating layer, the second insulating layer and the third insulating layer to expose a portion of the first gate line; and
forming a first conductive element on the third insulating layer, the portion of the first gate line and the portion of the second gate line, so that the first conductive element is electrically connected to the first gate line and the second gate line.

18. The method for manufacturing an electronic device as claimed in claim 17, wherein the step of penetrating the third insulating layer and the step of penetrating the first insulating layer, the second insulating layer and the third insulating layer are performed in the same process.

19. The method for manufacturing an electronic device as claimed in claim 17, wherein the first insulating layer, the second insulating layer and the third insulating layer are penetrated to form a first opening with a first width, and the third insulating layer is penetrated to form a second opening with a second width, and the first width is greater than the second width.

20. The method for manufacturing an electronic device as claimed in claim 19, wherein there is more than one first opening, and there is more than one second opening.
